(19) United States
(12) Patent Application Publication
(10) Pub. No.: US 2024/0153816 A1
(43) Pub. Date: May 9, 2024

(54) METHODS TO FORM METAL LINERS FOR INTERCONNECTS

(71) Applicant: Applied Materials, Inc., Santa Clara, CA (US)

(72) Inventors: Ge QU, Sunnyvale, CA (US); Zhiyuan WU, San Jose, CA (US); Jiajie CEN, San Jose, CA (US); Feng CHEN, San Jose, CA (US)

(21) Appl. No.: 17/980,850

(22) Filed: Nov. 4, 2022

(51) Int. Cl. H01L 21/768

(52) U.S. Cl. CPC H01L 21/76855; H01L 21/7685; H01L 21/76864; H01L 21/76882

(57) ABSTRACT

A method for forming a metal liner layer for an interconnect uses a multi-metal deposition process to produce a reduced thickness liner. The back-end-of-the-line packaging process may include forming a metal liner layer by depositing a ruthenium layer with a first thickness of approximately 5 angstroms or less and depositing a first cobalt layer with a second thickness of approximately 20 angstroms or less. In some embodiments, the ruthenium layer may be deposited on a previously formed barrier layer and then undergoes a treatment process before depositing the first cobalt layer. In some embodiments, the first cobalt layer may be deposited on the ruthenium layer or the ruthenium layer maybe deposited on the first cobalt layer. In some embodiments, the ruthenium layer is deposited on the first cobalt layer and a second cobalt layer is deposited on the ruthenium layer.

### FIELD

Embodiments of the present principles generally relate to semiconductor processing of semiconductor substrates.

### BACKGROUND

In order to increase the density of components on a chip, the critical dimensions (CDs) are scaled to ever decreasing sizes. The smaller dimensions directly impact the performance of interconnects used to provide electrical pathways for the semiconductor structures. During back-end-of-the-line (BEOL) packaging processes, the smaller dimensions generally cause an increase in resistivity of the interconnects. The inventors have observed that the resistivity in some cases can be attributed to reduced copper gapfill volume as the CD decreases because the liner layer thickness cannot be reduced without affecting the liner's performance.

Accordingly, the inventors have provided a method for forming metal liners that improve copper gapfill volume, allowing for increased density of interconnects while improving interconnect resistivity.

### SUMMARY

Methods for forming an enhanced metal liner layer are provided herein.

In some embodiments, a method for forming a metal liner layer for an interconnect may comprise depositing the metal liner layer in a back-end-of-the-line packaging process on at least a portion of an underlying copper interconnect layer, the depositing of the metal liner layer including depositing a first ruthenium layer with a first thickness of approximately 5 angstroms or less and depositing a first cobalt layer with a second thickness of approximately 20 angstroms or less.

In some embodiments, the method for forming the metal liner layer may further include depositing the first ruthenium layer on a previously formed barrier layer, performing a treatment process, and depositing the first cobalt layer on the first ruthenium layer after the treatment process; depositing copper gapfill material in an opening in which the metal liner layer has been deposited and annealing the copper gapfill material to reflow the copper gapfill material into the opening; forming an interfacial layer between the first ruthenium layer and the first cobalt layer to increase thermal stability of the metal liner layer; depositing the first ruthenium layer on the first cobalt layer; depositing the first cobalt layer on the first ruthenium layer; depositing the first cobalt layer, depositing the first ruthenium layer on the first cobalt layer, and depositing a second cobalt layer on the first ruthenium layer; where the second thickness is approximately 10 angstroms or less, the first thickness is approximately 5 angstroms, and a third thickness of the second cobalt layer is approximately 10 angstroms or less; where the second thickness is approximately 12 angstroms or less; and/or depositing the first ruthenium layer, wherein the first thickness is approximately 2.5 angstroms or less, depositing the first cobalt layer on the first ruthenium layer, and depositing a second ruthenium layer on the first cobalt layer, wherein a third thickness of the second ruthenium layer is approximately 2.5 angstroms or less.

In some embodiments, a method for forming a metal liner layer for an interconnect may comprise depositing the metal liner layer in a back-end-of-the-line packaging process on at least a portion of a conductive material in an underlying interconnect layer, the depositing of the metal liner layer including depositing a first metal layer of a first metal material with properties that impede migration of the conductive material on the first metal layer to a reduced reflow rate when a first thickness of the first metal layer is less than 30 angstroms and depositing a second metal layer of a second metal material different from the first metal material with properties that enhance migration of the conductive material on the metal liner layer to increase the reduced reflow rate of the conductive material, wherein the second metal layer has a second thickness that is approximately 5 percent to approximately 30% of the first thickness.

In some embodiments, a non-transitory, computer readable medium having instructions stored thereon that, when executed, cause a method for forming a metal liner layer for an interconnect to be performed, the method may comprise depositing the metal liner layer in a back-end-of-the-line packaging process on at least a portion of an underlying copper interconnect layer, the depositing of the metal liner layer including depositing a first ruthenium layer with a first thickness of approximately 5 angstroms or less and depositing a first cobalt layer with a second thickness of approximately 20 angstroms or less.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional view of multiple interconnect layers on a substrate in accordance with some embodiments of the present principles.

FIG. 2 depicts a cross-sectional view of a metal liner layer formed in an opening of a substrate in accordance with some embodiments of the present principles.

FIG. 3 depicts a cross-sectional view of migration of underlying metal interconnect layer into an opening in accordance with some embodiments of the present principles.

FIG. 4 depicts a cross-sectional view of a metal liner layer formed of multiple metal materials in accordance with some embodiments of the present principles.

FIG. 5 depicts cross-sectional views of a metal liner layer in accordance with some embodiments of the present principles.

FIG. 6 depicts a cross-sectional view of portions of a metal liner layer deposited prior to and after a treatment process in accordance with some embodiments of the present principles.

FIG. 7 is a method of forming an interconnect layer on a conductive material in a BEOL packaging process in accordance with some embodiments of the present principles.

FIG. 8 are methods of forming a metal line layer on a conductive material in accordance with some embodiments of the present principles.

FIG. 9 is a method of forming a metal line layer on a conductive material in accordance with some embodiments of the present principles.

FIG. 10 depicts a cluster tool in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide an enhanced metal liner with reduced thickness that allows for more gapfill volume and reduced interconnect resistivity as critical dimensions (CDs) are decreased. The methods deposit a doped (metal layer combined with a thin metal layer of differing material) metal liner via a chemical vapor deposition (CVD) process for interconnect scaling. In some embodiments, the use of a doped metal liner enables liner scale down for interconnect level cobalt (Co) only liners while maintaining copper (Cu) reflow properties and preventing underlayer Cu voiding caused by using a thick ruthenium (Ru) liner. The reduction of liner thickness enables increased Cu gapfill with the accompanying line resistance reduction benefit.

Cobalt liners have been previously used to provide a Cu reflow interface for Cu gapfill. Although Ru liners provide better Cu reflow properties than a Co liner, the use of Ru liners is limited due to underlayer Cu voiding caused by Cu diffusion on the Ru liner. With interconnects scaling down, the traditional Co liner thickness inhibits via contact resistance (Rc) and line resistance (R) improvement, and, therefore, liner thickness reduction is needed for future technology nodes. The methods disclosed herein use a Ru/Co liner that provides sufficient Cu reflow properties in a small structure and prevents underlayer Cu voiding. A Ru doped Co liner according to the present principles adds a small amount of Ru (e.g., approximately 5A or less in thickness) to a Co layer (e.g., approximately 20A or less in thickness), to enable liner scale down (e.g., metal liner layer total thickness of approximately 25A or less of Ru doped Co) compared to traditional cobalt liners of 30A to 35A. The doped Ru provides better adhesion of the Co with, for example, a tantalum nitride (TaN) barrier layer and helps with Cu reflow, while the small amount of Ru does not cause Cu voiding.

The methods of the present principles form a metal liner layer for back-end-of the-line (BEOL) packaging processes that include Ru doped Co liners that incorporate a small amount of Ru into the Co liner during CVD deposition of liners. Ru doping can occur before, during or after Co deposition depending on the design of the structure. The Ru doped Co combination gives better metal liner stability when undergoing thermal annealing compared to a Co only liner. The Ru doped Co metal liner also has improved Cu gapfill capability compared to a Co only liner at the same thickness (e.g., a 3A Ru layer+a 17 A Co layer vs a 20A Co only layer). The Ru doped Co metal liner also gives a line R benefit when comparing traditional Co only liners because a thinner Ru doped Co liner allows for more Cu gapfill than a traditional Co only liner.

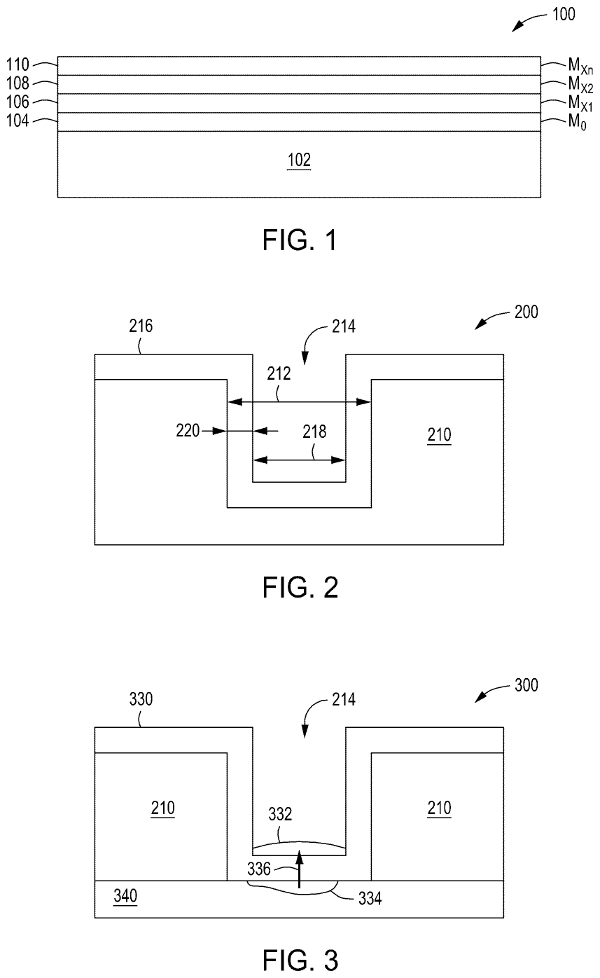

In the view 100 of FIG. 1 a substrate 102 produced in, for example, a front-end-of-the-line (FEOL) process is shown with multiple interconnect layers formed in BEOL packaging processes. The first interconnect layer, MO 104, can be formed using a thick ruthenium containing liner layer because no underlying copper is present on the substrate 102. However, subsequent interconnect layers such as MX1 106, MX2 108, and MXN 110 cannot be formed with a ruthenium liner layer due to migration issues of the underlying copper in the previously formed interconnect layer. As depicted in a view 200 of FIG. 2, cobalt is then used as the liner layer material to produce a cobalt liner layer 216 on an opening 214 of an MX layer 210. The cobalt liner layer 216 traditionally has a thickness 220 of 30 angstroms to 35 angstroms. The thickness 220 of the cobalt liner layer 216 directly impacts a width 212 of the opening 214, reducing a gapfill opening width 218. As the CD decreases, the thickness 220 of the cobalt liner layer 216 will substantially impact the gapfill volume and dramatically increase the interconnect resistivity. The inventors investigated using a cobalt liner with a thickness of approximately 20 angstroms and found a large number of defects that would inhibit the use of such a liner (the cobalt only liner was unable to fill small vias causing voids). The methods of the present principles provide liners that may be applied to all interconnect levels.

As depicted in a view 300 of FIG. 3, the inventors also found that the use of a thick ruthenium liner layer 330 on the MX layer 210 causes copper migration 336 issues from an underlying copper interconnect 340. The copper material migrates from the underlying copper interconnect 340 through the thick ruthenium liner layer 330 and into the opening 214 forming copper material 332 in the opening. The migrating copper from the underlying copper interconnect 340 leaves a void 334 in the underlying copper interconnect 340, reducing the performance of the underlying copper interconnect 340. The inventors further experimented with a liner using ruthenium and cobalt as the metal liner materials.

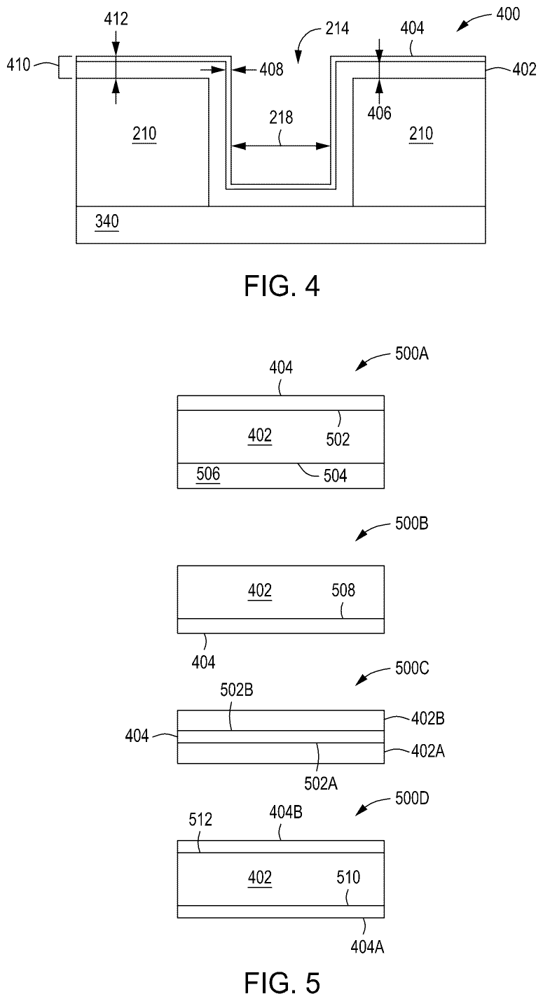

As depicted in a view 400 of FIG. 4, the inventors discovered that by using a combination of materials in a metal liner layer 410, a thinner liner layer could be achieved while still preventing the migration of underlying interconnect metals. In some embodiments, a first metal liner layer 402 (e.g., cobalt, etc.) is formed in the opening 214 with a first thickness 406 of approximately 20 angstroms or less. A second metal liner layer 404 (e.g., doping layer of Ru, W, Mn, Ta, etc.) of a material different from the first metal liner layer 402 is formed on the first metal liner layer 402 with a second thickness 408 of approximately 5 angstroms or less. In the example, the metal liner layer 410 has a third thickness 412 of approximately 25 angstroms or less, substantially thinner than the traditional cobalt liner thickness of 30 to 35 angstroms while still able to fill small vias due to the addition of the second metal liner material. With the thinner metal liner, the gapfill opening width 218 is increased, allowing a greater volume of gapfill material and a substantially reduced resistivity of the interconnect. In some embodiments, a cobalt layer of approximately 17 angstroms and a ruthenium layer of approximately 3 angstroms yielded a metal liner layer with a liner layer thickness of approximately 20 angstroms with void free copper gapfill results. In some embodiments, a cobalt layer of approximately 12 angstroms and a ruthenium layer of approximately 3 angstroms yielded a metal liner layer with a thickness of approximately 15 angstroms with void free copper gapfill results within 10% to 15% of the thicker 20 angstrom liner layer of the present principles.

In addition, the inventors found that liner dewetting tests showed that the 15 angstrom metal liner layer and the 20 angstrom metal liner layer of the present principles were substantially equal in sheet resistivity (thermal stability due to the use of ruthenium) at 400 degrees Celsius for the first 30 minutes of annealing time with minor variations thereafter. In some embodiments, the second thickness 408 of the second metal liner layer 404 may be approximately 5% to approximately 30% of the first thickness 406 of the first metal liner layer 402. The inventors found that a balance can be achieved between the ratios of the different metal materials of the metal liner layer and the required increase in gapfill volume in a particular design. For example, a slight increase in void yield due to the use of a thinner metal liner layer of the present principles may be tolerable if a higher performance (low resistance, increased gapfill volume) interconnect is desired. Additional tuning parameters such as, for example, temperature, precursor gas flow rate, and/or pressure may be used during deposition of the different metal materials of the metal liner layer of the present principles.

In some embodiments, depicted in a view 500A of FIG. 5, the first metal liner layer 402 is deposited first on an underlying conductive interconnect 506. The second metal liner layer 404 is deposited on the first metal liner layer 402. The metal material deposited for the second metal liner layer 404 is different from the metal material deposited for the first metal liner layer 402. The inventors have found that deposition of the first metal liner layer 402, for example cobalt, on the underlying conductive interconnect 506 allows the cobalt material of the first metal liner layer 402 to form a better first interfacial layer 504 with the underlying conductive interconnect 506. Deposition of the second metal liner layer 404, for example ruthenium, on the first metal liner layer 402, forms a second interfacial layer 502 with the first metal liner layer 402 and aids in the reflow of the gapfill material during subsequent annealing processes. In some embodiments, depicted in a view 500B of FIG. 5, the second metal liner layer 404 is deposited first. The first metal liner layer 402 is deposited on the second metal liner layer 404. The metal material deposited for the second metal liner layer 404 is different from the metal material deposited for the first metal liner layer 402. The inventors have found that deposition of the first metal liner layer 402, for example cobalt, on the second metal liner layer 404, forms a third interfacial layer 508 with the second metal liner layer 404 and provides improved thermal stability during subsequent annealing process (i.e., less impact on resistivity after applying heat).

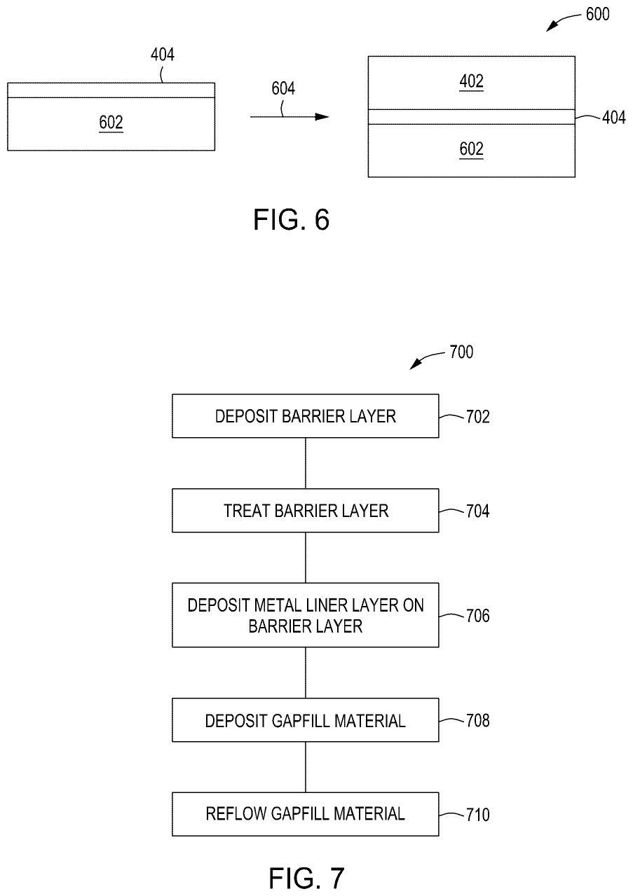

In some embodiments, depicted in a view 500C of FIG. 5, a first metal liner layer 402A is deposited first. The first metal liner layer 402A may have a thickness of approximately 10 angstroms or less. The second metal liner layer 404 is deposited on the first metal liner layer 402A. A third metal liner layer 402B is deposited on the second metal liner layer 404. The third metal liner layer 402B is formed with the same metal material as the first metal liner layer 402A. The metal material deposited for the second metal liner layer 404 is different from the metal material deposited for the first metal liner layer 402A and the third metal liner layer 402B. The third metal liner layer 402B may have a thickness of approximately 10 angstroms or less. During deposition of the layers, a third interfacial layer 502A is formed between the first metal liner layer 402A and the second metal liner layer 404. A fourth interfacial layer 502B is formed between the second metal liner layer 404 and the third metal liner layer 402B. In some embodiments, depicted in a view 600 of FIG. 6, the second metal liner layer 404 may be deposited on a barrier layer 602 and then subjected to a treatment process 604 prior to the deposition of the first metal liner layer 402. The treatment process 604 may include a plasma treatment in a physical vapor deposition (PVD) chamber with argon and the like. In some instances, the metal material, such as ruthenium, of the second metal liner layer 404 may be used in forming the barrier layer 602, allowing for easy deposition of the first metal liner layer 402 and a streamlined barrier/liner layer process.

In some embodiments, depicted in a view 500D of FIG. 5, a first second metal liner layer 404A is deposited first. The first metal liner layer 402 is deposited on the first second metal liner layer 404A. The metal material deposited for the first second metal liner layer 404A is different from the metal material deposited for the first metal liner layer 402. The inventors have found that deposition of the first metal liner layer 402, for example cobalt, on the first second metal liner layer 404A, forms a fourth interfacial layer 510 with the first second metal liner layer 404A and a fifth interfacial layer 512 with the second second metal liner layer 404B and provides improved thermal stability during subsequent annealing process (i.e., less impact on resistivity after applying heat).

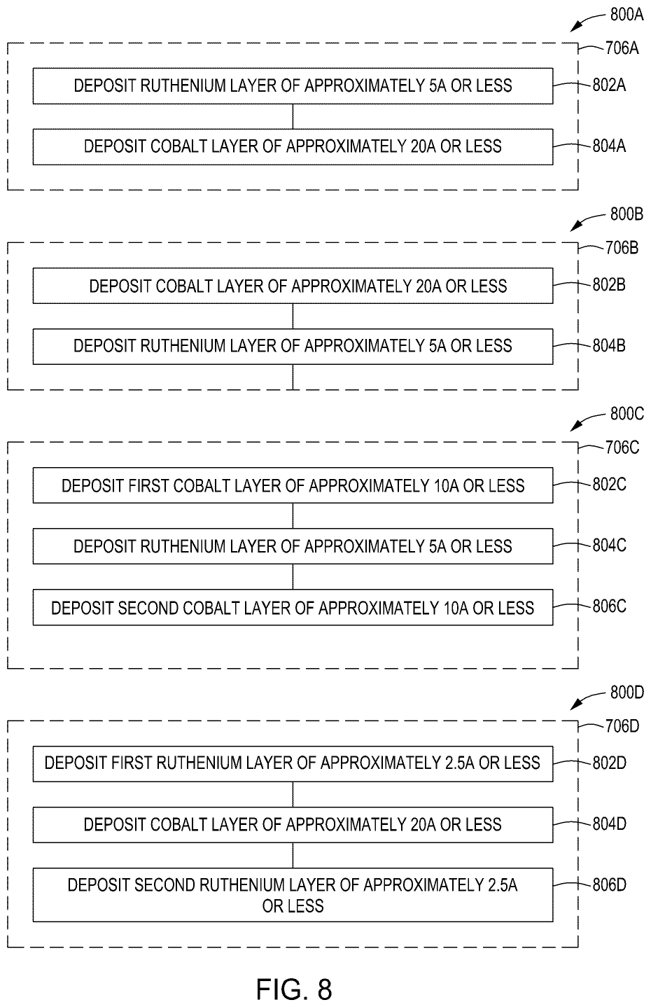

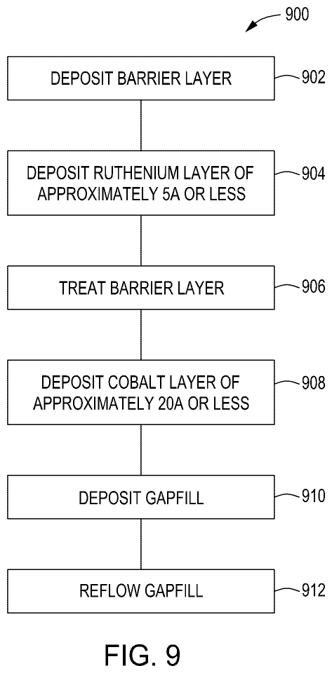

In some embodiments, a BEOL packaging process may include a method 700 for forming an interconnect in a low-k material. In block 702, a barrier layer is deposited on a subsequently formed interconnect layer. In block 704, the barrier layer is treated with a treatment process such as an argon treatment and the like. In block 706, a metal liner layer of the present principles is deposited on the barrier layer. In some embodiments, the metal liner layer may be deposited using an atomic layer deposition (ALD) process, a chemical vapor deposition (CVD) process, or a physical vapor deposition (PVD) process in a single chamber or using multiple chambers. The metal liner incorporates a first metal material (e.g., cobalt, and the like) that exhibits properties with a reduced reflow rate of subsequently deposited conductive gapfill material when a thickness of the first metal material is less than 30 angstroms. By doping the cobalt material with a second metal material such as ruthenium, tantalum, tungsten, manganese, and the like which enhances migration of the conductive gapfill on the metal liner, the reduced reflow rate of the first metal material can be increased while the overall thickness of the metal liner is decrease (over traditional liner thicknesses). In block 708, conductive gapfill material is deposited on the metal liner layer. In block 710, the conductive gapfill material is annealed to reflow the gapfill material and form the conductive interconnect. In some embodiments, deposition methods of the metal liner layer of block 706 may include some embodiments (706A, 706B, 706C) as depicted in views 800A, 800B, 800C, and 800D of FIG. 8. In block 802A, a ruthenium layer is deposited with a thickness of approximately 5 angstroms or less (see, e.g., view 500B of FIG. 5). In block 804A, a cobalt layer of approximately 20 angstroms or less is deposited on the ruthenium layer (see, e.g., view 500B of FIG. 5). In some embodiments, other metal materials may be used in place of the ruthenium metal materials such as, for example, tungsten, manganese, tantalum, etc.

In block 802B, a cobalt layer is deposited with a thickness of approximately 20 angstroms or less (see, e.g., view 500A of FIG. 5). In block 804B, a ruthenium layer of approximately 5 angstroms or less is deposited on the cobalt layer (see, e.g., view 500A of FIG. 5). In some embodiments, other metal materials may be used in place of the ruthenium metal materials such as, for example, tungsten, manganese, tantalum, etc. In block 802C, a first cobalt layer is deposited with a thickness of approximately 10 angstroms or less (see, e.g., view 500C of FIG. 5). In block 804C, a ruthenium layer of approximately 5 angstroms or less is deposited on the cobalt layer (see, e.g., view 500C of FIG. 5). In block 806C, a second cobalt layer is deposited with a thickness of approximately 10 angstroms or less (see, e.g., view 500C of FIG. 5). In some embodiments, other metal materials may be used in place of the ruthenium metal materials such as, for example, tungsten, manganese, tantalum, etc. In block 802D, a first ruthenium layer is deposited with a thickness of approximately 2.5 angstroms or less (see, e.g., view 500D of FIG. 5). In block 804D, a cobalt layer of approximately 20 angstroms or less is deposited on the cobalt layer (see, e.g., view 500D of FIG. 5). In block 806D, a second ruthenium layer is deposited with a thickness of approximately 2.5 angstroms or less (see, e.g., view 500D of FIG. 5). In some embodiments, other metal materials may be used in place of the ruthenium metal materials such as, for example, tungsten, manganese, tantalum, etc.

In some embodiments, a BEOL packaging process may include a method 900 for forming an interconnect in a low-k material. In block 902, a barrier layer is deposited on a subsequently formed interconnect layer. In block 904, a ruthenium layer of approximately 5 angstroms or less is deposited on the barrier layer. In block 906, the barrier layer is treated with a treatment process such as a PVD argon treatment and the like. In block 908, a cobalt layer of the present principles is deposited on the ruthenium layer with a thickness of approximately 20 angstroms or less. In block 910, conductive gapfill material is deposited on the metal liner layer. In block 912, the conductive gapfill material is annealed to reflow the gapfill material and form the conductive interconnect. The incorporation of the deposition of the ruthenium in the barrier deposition process allows for a more streamlined packaging process. In some embodiments, other metal materials may be used in place of the ruthenium and cobalt metal materials such as, for example, tungsten, manganese, tantalum, etc.).

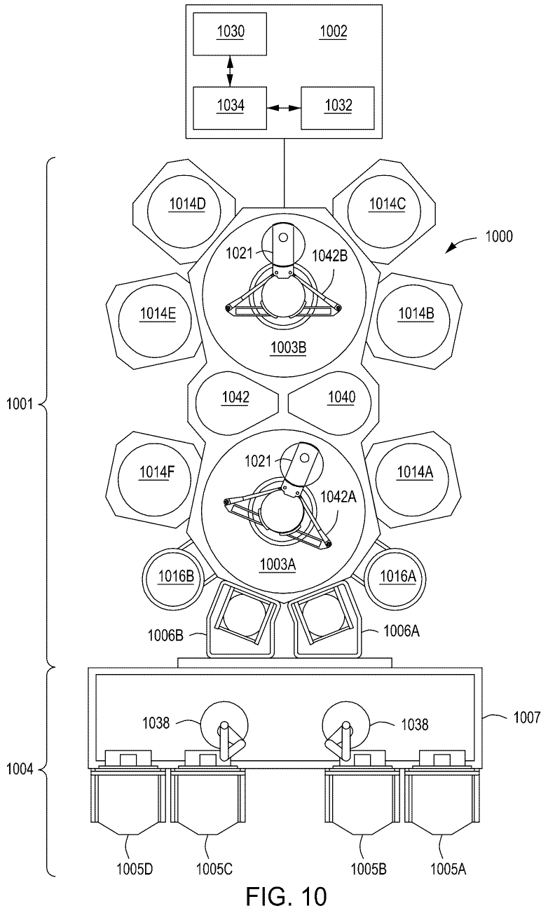

The methods described herein may be in a single process chamber or performed in a single process chamber or multiple process chambers that may be provided as part of a cluster tool, for example, the integrated tool 1000 (i.e., cluster tool) described below with respect to FIG. 10. The advantage of using an integrated tool 1000 is that there is no vacuum break between chambers and, therefore, no requirement to degas and pre-clean a substrate before treatment or deposition in a chamber. For example, in some embodiments the inventive methods discussed above may advantageously be performed in an integrated tool such that there are limited or no vacuum breaks between processes, limiting or preventing contamination of the substrate such as oxidation and the like. The integrated tool 1000 includes a vacuum-tight processing platform 1001, a factory interface 1004, and a system controller 1002. The processing platform 1001 comprises multiple processing chambers, such as 1014A, 1013B, 1014C, 1014D, 1014E, and 1014F operatively coupled to a vacuum substrate transfer chamber (transfer chambers 1003A, 1003B). The factory interface 1004 is operatively coupled to the transfer chamber 1003A by one or more load lock chambers (two load lock chambers, such as 1006A and 1006B shown in FIG. 10).

In some embodiments, the factory interface 1004 comprises at least one docking station 1007, at least one factory interface robot 1038 to facilitate the transfer of the semiconductor substrates. The docking station 1007 is configured to accept one or more front opening unified pod (FOUP). Four FOUPS, such as 1005A, 1005B, 1005C, and 1005D are shown in the embodiment of FIG. 10. The factory interface robot 1038 is configured to transfer the substrates from the factory interface 1004 to the processing platform 1001 through the load lock chambers, such as 1006A and 1006B. Each of the load lock chambers 1006A and 1006B have a first port coupled to the factory interface 1004 and a second port coupled to the transfer chamber 1003A. The load lock chamber 1006A and 1006B are coupled to a pressure control system (not shown) which pumps down and vents the load lock chambers 1006A and 1006B to facilitate passing the substrates between the vacuum environment of the transfer chamber 1003A and the substantially ambient (e.g., atmospheric) environment of the factory interface 1004. The transfer chambers 1003A, 1003B have vacuum robots 1042A, 1042B disposed in the respective transfer chambers 1003A, 1003B. The vacuum robot 1042A is capable of transferring substrates 1021 between the load lock chamber 1006A, 1006B, the processing chambers 1014A and 1014F and a cooldown station 1040 or a pre-clean station 1042. The vacuum robot 1042B is capable of transferring substrates 1021 between the cooldown station 1040 or pre-clean station 1042 and the processing chambers 1014B, 1014C, 1014D, and 1014E.

In some embodiments, the processing chambers 1014A, 1014B, 1014C, 1014D, 1014E, and 1014F are coupled to the transfer chambers 1003A, 1003B. The processing chambers 1014A, 1014B, 1014C, 1014D, 1014E, and 1014F may comprise, for example, preclean chambers, ALD process chambers, PVD process chambers, remote plasma chambers, CVD chambers, or the like. The chambers may include any chambers suitable to perform all or portions of the methods described herein, as discussed above, such as CVD chambers or ALD chambers and the like. In some embodiments, one or more optional service chambers (shown as 1016A and 1016B) may be coupled to the transfer chamber 1003A. The service chambers 1016A and 1016B may be configured to perform other substrate processes, such as degassing and argon treatments, and the like.

The system controller 1002 controls the operation of the tool 1000 using a direct control of the process chambers 1014A, 1014B, 1014C, 1014D, 1014E, and 1014F or alternatively, by controlling the computers (or controllers) associated with the process chambers 1014A, 1014B, 1014C, 1014D, 1014E, and 1014F and the tool 1000. In operation, the system controller 1002 enables data collection and feedback from the respective chambers and systems to optimize performance of the tool 1000. The system controller 1002 generally includes a Central Processing Unit (CPU) 1030, a memory 1034, and a support circuit 1032. The CPU 1030 may be any form of a general-purpose computer processor that can be used in an industrial setting. The support circuit 1032 is conventionally coupled to the CPU 1030 and may comprise a cache, clock circuits, input/output subsystems, power supplies, and the like. Software routines, such as a method as described above may be stored in the memory 1034 and, when executed by the CPU 1030, transform the CPU 1030 into a specific purpose computer (system controller) 1002. The software routines may also be stored and/or executed by a second controller (not shown) that is located remotely from the tool 1000.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for forming a metal liner layer for an interconnect, comprising:
depositing the metal liner layer in a back-end-of-the-line packaging process on at least a portion of an underlying copper interconnect layer, the depositing of the metal liner layer including:
depositing a first ruthenium layer with a first thickness of approximately 5 angstroms or less; and
depositing a first cobalt layer with a second thickness of approximately 20 angstroms or less.

2. The method of claim 1, further comprising:
depositing the first ruthenium layer on a previously formed barrier layer;
performing a treatment process; and
depositing the first cobalt layer on the first ruthenium layer after the treatment process.

3. The method of claim 1, further comprising:
depositing copper gapfill material in an opening in which the metal liner layer has been deposited; and
annealing the copper gapfill material to reflow the copper gapfill material into the opening.

4. The method of claim 1, further comprising:
forming an interfacial layer between the first ruthenium layer and the first cobalt layer to increase thermal stability of the metal liner layer.

5. The method of claim 1, further comprising:
depositing the first ruthenium layer on the first cobalt layer.

6. The method of claim 1, further comprising:
depositing the first cobalt layer on the first ruthenium layer.

7. The method of claim 1, further comprising:
depositing the first cobalt layer;
depositing the first ruthenium layer on the first cobalt layer; and
depositing a second cobalt layer on the first ruthenium layer.

8. The method of claim 7, wherein the second thickness is approximately 10 angstroms or less, the first thickness is approximately 5 angstroms, and a third thickness of the second cobalt layer is approximately 10 angstroms or less.

9. The method of claim 1, wherein the second thickness is approximately 12 angstroms or less.

10. The method of claim 1, further comprising:
depositing the first ruthenium layer, wherein the first thickness is approximately 2.5 angstroms or less;
depositing the first cobalt layer on the first ruthenium layer; and
depositing a second ruthenium layer on the first cobalt layer, wherein a third thickness of the second ruthenium layer is approximately 2.5 angstroms or less.

11. A method for forming a metal liner layer for an interconnect, comprising:
depositing the metal liner layer in a back-end-of-the-line packaging process on at least a portion of a conductive material in an underlying interconnect layer, the depositing of the metal liner layer including:
depositing a first metal layer of a first metal material with properties that impede migration of the conductive material on the first metal layer to a reduced reflow rate when a first thickness of the first metal layer is less than 30 angstroms; and
depositing a second metal layer of a second metal material different from the first metal material with properties that enhance migration of the conductive material on the metal liner layer to increase the reduced reflow rate of the conductive material, wherein the second metal layer has a second thickness that is approximately 5 percent to approximately 30% of the first thickness.

12. The method of claim 11, wherein the first metal material is cobalt, the second metal material is ruthenium, tungsten, manganese, or tantalum, and the conductive material is copper.

13. The method of claim 12, wherein the second thickness is approximately 5 angstroms or less and the first thickness is approximately 20 angstroms or less.

14. The method of claim 11, wherein the metal liner layer has a liner thickness of approximately 25 angstroms or less.

15. The method of claim 11, further comprising:
depositing the second metal layer on a previously formed barrier layer;
performing a treatment process; and
depositing the first metal layer on the second metal layer after the treatment process.

16. The method of claim 11, further comprising:
depositing a conductive gapfill material in an opening in which the metal liner layer has been deposited; and
annealing the conductive gapfill material to reflow the conductive gapfill material into the opening.

17. The method of claim 11, further comprising:
depositing the second metal layer on the first metal layer; or
depositing the first metal layer on the second metal layer.

18. The method of claim 11, further comprising:
depositing the first metal layer;
depositing the second metal layer on the first metal layer; and
depositing a third metal layer of first metal material on the second metal layer.

19. A non-transitory, computer readable medium having instructions stored thereon that, when executed, cause a method for forming a metal liner layer for an interconnect to be performed, the method comprising:
depositing the metal liner layer in a back-end-of-the-line packaging process on at least a portion of an underlying copper interconnect layer, the depositing of the metal liner layer including:
depositing a first ruthenium layer with a first thickness of approximately 5 angstroms or less; and
depositing a first cobalt layer with a second thickness of approximately 20 angstroms or less.

20. The non-transitory, computer readable medium of claim 19, further comprising one of a, b, c, d, ore:
(a) depositing the first ruthenium layer on a previously formed barrier layer;
performing a treatment process; and
depositing the first cobalt layer on the first ruthenium layer after the treatment process; or
(b) depositing the first ruthenium layer on the first cobalt layer; or
(c) depositing the first cobalt layer on the first ruthenium layer; or
(d) depositing the first cobalt layer, wherein the second thickness is approximately 10 angstroms or less;
depositing the first ruthenium layer on the first cobalt layer; and
depositing a second cobalt layer on the first ruthenium layer, wherein a third thickness of the second cobalt layer is approximately 10 angstroms or less; or
(e) depositing the first ruthenium layer, wherein the first thickness is approximately 2.5 angstroms or less;
depositing the first cobalt layer on the first ruthenium layer; and
depositing a second ruthenium layer, wherein a third thickness of the second ruthenium layer is approximately 2.5 angstroms or less.
